(19) United States
(12) Patent Application Publication
(10) Pub. No.: US 2025/0183613 A1
(43) Pub. Date: Jun. 5, 2025

(54) LASER SOURCE HAVING A PLURALITY OF SPECTRAL LINES SEPARATED BY A DETERMINED SPECTRAL INTERVAL

(71) Applicant: SCINTIL PHOTONICS, Grenoble (FR)

(72) Inventors: Sylvie Menezo, Grenoble (FR); Florian Enault

(73) Assignee: SCINTIL PHOTONICS, Grenoble (FR)

(21) Appl. No.: 18/842,588

(22) PCT Filed: Mar. 14, 2023
(86) PCT No.: PCT/EP2023/056422

§ 371 Date: Aug. 29, 2024

(30) Foreign Application Priority Data
Mar. 15, 2022 (FR) FR2202254
May 24, 2022 (FR) FR2204950
Jul. 25, 2022 (FR) FR2207600

(51) Int. Cl. H01S 5/00; H01S 5/06; H01S 5/0687; H01S 5/125; H01S 5/14

(52) U.S. Cl. CPC H01S 5/0078; H01S 5/0085; H01S 5/0612; H01S 5/0687; H01S 5/142; H01S 5/125

(57) ABSTRACT

The invention relates to a laser source for emitting multispectral light emission having a plurality of spectral lines separated by a determined spectral interval. The laser source comprises a bank of tunable lasers, an optical filter having a plurality of resonant frequencies, a photodetector arranged downstream of the optical filter in order to establish a signal representative of the multispectral radiation, a modulator associated with the bank of tunable lasers, the modulator being capable of modulating by a modulation frequency the emission frequency of the light emission emitted by at least one tunable laser of the bank. The laser source also comprises a locking device of at least one tunable laser configured to process the signal representative of the multispectral radiation and to adjust the emission frequency to a resonant frequency of the filter.

### FIELD OF THE INVENTION

The present invention relates to a laser source for emitting a light emission having a plurality of spectral lines separated by a determined spectral interval. Such a source finds very particular application in the field of communications using wavelength division multiplexing.

### BACKGROUND OF THE INVENTION

The document “WDM Source Based on High-Power, Efficient 1280-nm DFB Lasers for Terabit Interconnect Technologies”, B. Buckley, IEEE PHOTONICS TECHNOLOGY LETTERS, VOL. 30, NO. 22, Nov. 15, 2018, proposes a laser source formed from a bank of distributed feedback lasers. Each laser comprises a Bragg grating distributed along the laser cavity. The lasers emit light emissions at stepped wavelengths, typically separated from one another by 100 GHz or 50 GHz.

The light emissions emitted by the lasers are propagated to the input ports of a passive optical mixer. This mixer produces, on its output ports, a plurality of light emissions each combining the light emissions provided on its input ports. The output emissions produced on these output ports are therefore multispectral (in a spectral comb, each line of the comb corresponding to the emission emitted by a laser of the bank).

Due to inaccuracies and variability in laser manufacturing methods, laser emission wavelengths are poorly controlled. This leads to variability in the spectral interval between two spectral lines in multispectral emission, of the order of plus or minus 5 to 10% of the expected spectral interval, or even more depending on the interval. The wavelengths of light emissions emitted by lasers are also sensitive to operating temperature, which can for example vary from 0 to 80° C.

The spectral range of the light emissions provided by a multispectral laser source of the state of the art is therefore poorly controlled and liable to drift during operation of this source.

Document WO2013044863 proposes a transmitter formed by a multispectral laser source composed of a plurality of lasers whose emission frequencies are adjustable. A generator associated with the lasers produces a pilot signal that modulates the laser emissions at low frequency. The multispectral emission produced by the transmitter is guided by an optical fiber to a remote etalon filter. Optical dividers, respectively positioned before and after the etalon filter, provide signals to a regulator. The regulator generates adjustment signals which are added to the modulation signals of the lasers to respectively lock their emissions to the wavelengths defined by the etalon filter.

It will be noted that in the solution proposed in this document, the etalon filter, remote from the laser source, is not subjected to the same temperature excursions as the source. This filter defines absolute etalon frequencies to which the laser emission frequencies are respectively conformed, by adjusting their power supply. This solution is unsatisfactory, as it can lead, when emission frequencies deviate significantly from standard frequencies, to the production of high-amplitude laser adjustment signals, which affect the power of the emissions emitted by the multispectral laser source, making it variable beyond acceptable thresholds.

### OBJECT OF THE INVENTION

One aim of the invention is to provide at least a partial solution to this problem. More specifically, one aim of the invention is to propose a laser source capable of providing multispectral light emissions whose spectral range is better controlled than that present in light emissions produced by prior art laser sources.

### BRIEF DESCRIPTION OF THE INVENTION

In order to achieve this aim, the object of the invention proposes a laser source for emitting at least one multispectral light emission having a plurality of spectral lines separated by a predetermined spectral interval, the laser source comprising:
a bank of tunable lasers, a spectral line of the multispectral light emission corresponding to a frequency, called the “emission frequency”, of the light emission emitted by a tunable laser of the bank;
means for adjusting the emission frequencies of the tunable lasers;
an optical filter having a plurality of resonant frequencies, two successive resonant frequencies being separated by the determined spectral interval, the optical filter being arranged optically downstream of the bank of tunable lasers, the optical filter being provided with a device for adjusting the plurality of resonant frequencies;
a photodetector arranged optically downstream of the optical filter to establish a signal representative of the multispectral light emission transmitted through the filter;
a modulator associated with means for adjusting the emission frequencies of the tunable lasers, the modulator being configured to generate a modulation signal and to modulate the emission frequency of the light emission emitted by at least one tunable laser of the bank;
a locking device connected to the means for adjusting the emission frequency of the tunable lasers and connected to the device for adjusting the plurality of resonant frequencies, the locking device being configured to process the signal representative of the multispectral emission and to lock the emission frequencies of the tunable lasers to the resonant frequencies of the filter.

According to other advantageous non-limiting features of the invention, taken alone or according to any technically feasible combination:
the laser source comprises an optical mixer associated with the bank of tunable lasers to combine the light emissions emitted by the tunable lasers of the bank and to provide the multispectral light emission to the filter;
the optical filter is a microring resonator;
the device for adjusting the plurality of resonant frequencies is a heater; the means for adjusting the emission frequency of the tunable lasers are selected from the following list: a current source, a heater, a free carrier injection/depletion device;
the lasers in the bank of tunable lasers are distributed feedback lasers or distributed Bragg reflector lasers;
the locking device is configured to control the modulator and to select, by means of a selection signal, the tunable laser to which the modulation signal is applied;
the modulator generates a plurality of mutually distinct modulation signals, the modulation signals being applied to the tunable lasers;
the modulator is configured to produce a sinusoidal modulation signal with a modulation frequency;
the locking device is configured to establish a measurement representative of the power present in a second harmonic and/or in a principal component and/or a measurement representative of the phase of the principal component of the modulation frequency of the signal representative of the multispectral emission;
the bank of tunable lasers and the optical filter are integrated on/in the same substrate of a photonic chip;
the temperature drift coefficient of tunable laser emission frequencies and the temperature drift coefficient of resonant frequencies are identical to within 10%.

According to another aspect, the invention proposes a method for using the laser source, the method being implemented by the locking device and comprising:
a control phase to activate the device for adjusting the plurality of resonant frequencies of the optical filter;
a locking phase to lock the light emission frequency of the selected tunable laser to a resonant frequency of the filter.

Advantageously, the locking phase takes place after the control phase.

### BRIEF DESCRIPTION OF THE DRAWINGS

Other features and advantages of the invention will emerge from the following detailed description of the invention with reference to the appended figures, in which:

FIGS. 1a, 1b, 1c, 1d and 1e show schematic diagrams of the principles underlying the invention;

FIG. 2a shows a first embodiment of the invention;

FIG. 2b shows a variant of the first embodiment of the invention;

FIG. 3a shows the transition from a natural state to the locked state of a laser source according to the invention;

FIG. 3b shows an advantageous feature of a filter transmission function of a laser source according to the invention;

FIG. 3c shows the calibration of a filter of a laser source according to an embodiment of the invention;

FIGS. 4 and 5 show further embodiments of the invention;

FIG. 6 shows the signal provided by the photodetector in the frequency domain, in the context of the embodiment of FIG. 5;

FIG. 7 shows a variant applicable to all embodiments of the invention; and

FIG. 8 shows the use of a source according to the second embodiment of the invention to tune a modulator array.

### DETAILED DESCRIPTION OF THE INVENTION

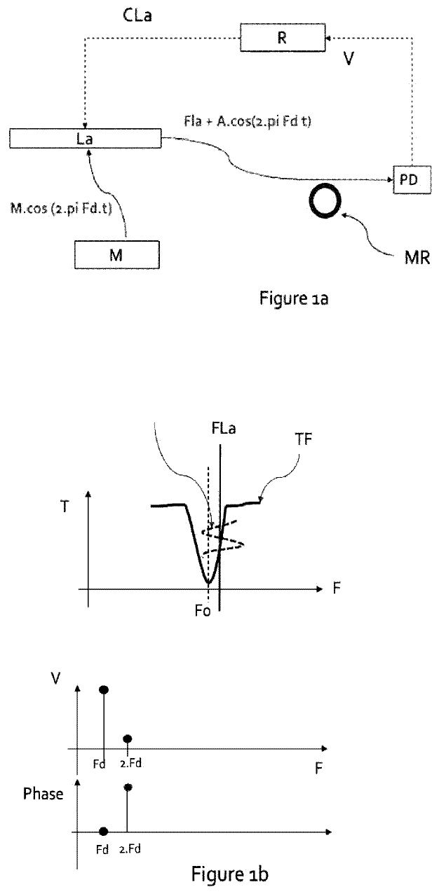

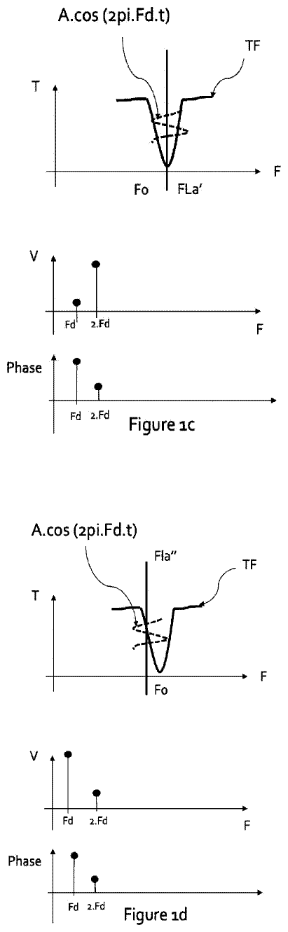

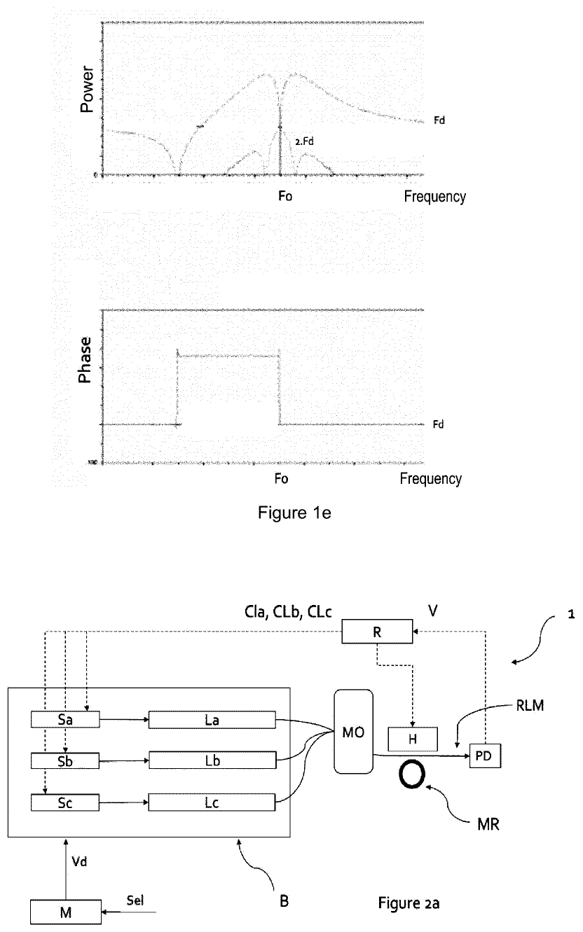

FIGS. 1a, 1b, 1c, 1d and 1e are schematic diagrams of the principles underlying the invention. In the architecture shown in FIG. 1a, a light emission from a tunable laser La is guided to a ring resonator MR, constituting a filter with a resonant frequency F0, and to a photodetector PD located downstream of the resonator MR.

The term “tunable laser” refers to a laser that produces a light emission at an adjustable frequency (“emission frequency”). By way of illustration, a means of adjusting the emission frequency with which the laser may be provided may comprise a device configured to modify its supply current, temperature, index and free carrier concentration. A tunable laser can be provided with a plurality of means for adjusting its emission frequency, e.g. an adjustable current source and a heater for modifying the laser's operating temperature.

A modulator M, connected to a laser emission frequency adjustment means, is configured to modulate the emission frequency Fla of the light emission emitted by the tunable laser La, by a modulation frequency Fd. This modulation frequency Fd, for example 5 kHz, is relatively low compared to the laser emission frequency, for example 200 terahertz. The amplitude of this modulation is also low. By way of example, 1 mA of supply current modulation amplitude can lead to a variation in the emission frequency FLa of the tunable laser La of the order of plus or minus 1 GHz. The light emission emitted by the tunable laser La therefore varies at very low frequency Fd and with low amplitude A (1 GHZ) around its fundamental frequency FLa. The laser frequency therefore varies as Fla+A.cos (2pi.Fd.t).

FIG. 1b shows the frequency-domain transmission function T of the filter MR, whose spectrum TF has a resonant frequency F0, and the signal V provided by this photodetector PD in the case where the emission frequency FLa of the tunable laser La is not locked to a resonant frequency F0 of the resonator MR, but has an emission frequency Fla higher than this resonant frequency F0. Since the emission frequency of the tunable laser La is located in a relatively linear section of the transmission function of the resonator MR, the signal V provided by the photodetector PD has, in the frequency domain, a principal component Fd (corresponding to the modulation frequency) that is relatively large with respect to its harmonics, and in particular with respect to its second harmonic 2*Fd. In addition, the phase of the principal component Fd of the signal V is reduced, that is, this principal component is in phase with the signal V provided by the photodetector PD.

Similarly to FIG. 1b, FIG. 1c shows the transmission function T of the filter MR, whose spectrum TF has a resonant frequency F0, and the signal V provided by this photodetector PD in the case where the emission frequency FLa′ of the tunable laser La is locked to the resonant frequency F0 of the resonator MR. In this case, the emission frequency FLa′ of the tunable laser La is arranged in a relatively non-linear section of the transmission function of the resonator MR. As a result, the signal V provided by the photodetector PD has relatively large harmonic components 2*Fd in the frequency domain, relative to the modulation frequency Fd.

Finally, FIG. 1d shows the frequency-domain transmission function T of the filter MR, whose spectrum TF has a resonant frequency F0, and the signal V provided by this photodetector PD in the case where the emission frequency FLa of the tunable laser La is not locked to a resonant frequency F0 of the resonator MR, but has an emission frequency Fla″ lower than this resonant frequency F0. Since the emission frequency of the tunable laser La is located in a relatively linear section of the transmission function of the resonator MR, the signal V provided by the photodetector PD has, in the frequency domain, a principal component Fd that is relatively large with respect to its harmonics, and in particular with respect to its second harmonic 2*Fd. Furthermore, the phase of the principal component Fd of the signal V is significant, that is, this principal component is in phase opposition with the signal V provided by the photodetector.

FIG. 1e summarizes the results of FIGS. 1b, 1c and 1d and shows, in the upper graph, the evolution of the power present in the principal component Fd and in the second harmonic 2*Fd of the signal V provided by the photodetector when the emission frequency FLa of the tunable laser La is modified and the resonant frequency of the filter remains fixed (or vice versa). FIG. 1e also shows, in the lower graph, the evolution of the phase of the principal component Fd of the signal V provided by the photodetector.

Returning to the description of the schematic diagram in FIG. 1a, a locking device R receives the signal V established by the photodetector and processes it to produce a command CLa for the tunable laser La to tune its emission frequency to lock it to the resonant frequency F0 of the resonator MR. The processing carried out by the locking device R takes advantage of the results shown in FIGS. 1b, 1c, 1d, 1e and determines the command to be applied to the means for adjusting the laser emission frequency, which maximizes the proportion of the signal present in the second harmonic 2*Fd of the signal provided by the photodetector PD. By way of illustration, the locking device R can apply a sequence of commands CLa to the adjustment device in increments from a minimum value to a maximum value so that the laser emission frequency La adjusts, in a succession of steps, from a minimum emission frequency to a maximum emission frequency. In each step, the locking device R applies a frequency transformation to the signal provided by the photodetector (e.g. a Fourrier transform) in order to detect the proportion of the signal present in the second harmonic. At the end of these steps, the step and the associated command CLa are identified that have led to a signal maximum in the second harmonic, this associated command CLa being the one that best matches the laser emission frequency La and the resonant frequency of the filter MR. This command is then applied to the laser emission frequency adjustment device La to cause the system to lock. Other approaches are also possible, for example by using the phase information of the main frequency Fd of the signal provided by the photodetector PD in a control loop that increments or decrements the command C1a provided to the frequency adjustment device by a predetermined pitch. As already noted, this information indicates whether the laser emission frequency is below the laser resonant frequency (high phase), or above it (zero or low phase).

The laser emission frequency La can be matched to the resonant frequency of the filter MR, as shown by way of example. Alternatively, they can be positioned at a specific distance from one another. Generally speaking, the command CLa is determined by optimizing a function that takes into account, for example, the proportion of the signal present in the principal component and/or in the second harmonic 2*Fd of the control signal V. The optimization criterion may be that the function reaches a target value, is below a predetermined ceiling value or is above a predetermined threshold value. The phase of the principal component and/or the second harmonic 2*Fd of the control signal V can also be evaluated.

For example, the ratio between the share of the signal present in the second harmonic and the share of the signal present in the principal component can be set to equal a target value or to maximize it.

For the sake of precision, we will therefore say that the system is “locked” when the chosen optimization criterion is met. This may correspond to the situation where the emission frequency Fla and the resonant frequency F0 match, or where these frequencies are offset from one another by a specified distance.

Note that by applying a sinusoidal modulation signal, the appearance of harmonics in the signal provided by the photodetector PD is limited (by comparison with square-wave modulation, for example), as the harmonics detected by the locking device R are then indeed representative of the quality of the locking between the emission frequency and the resonant frequency.

Note also that the same locking principles are applicable to a configuration where the laser has a fixed emission frequency, and where the adjustment device is associated with the filter so as to adjust its resonant frequency.

The present disclosure exploits the principles presented above to propose a laser source of multispectral light emission, thus presenting a plurality of spectral lines, these spectral lines being separated by a controlled spectral interval. By way of example, for applications in the field of wavelength-division multiplexing transmission, the aim is to provide a laser source of multispectral light emission whose spectral lines are precisely separated (to within 5%) by an interval of 100 GHz or 50 GHz, for example.

Referring to FIG. 2a, which shows a first embodiment of the invention, such a source 1 comprises a bank B of tunable lasers La, Lb, Lc. For example, the tunable lasers in the bank B can be distributed feedback lasers. As is well known, each laser comprises a Bragg grating distributed along a laser cavity. Each laser La, Lb, Lc of the bank B is associated with a current source Sa, Sb, Sc for power and light generation. As already noted, the emission frequency of a distributed feedback laser is dependent on its supply current. By adjusting this current, this emission frequency can be adjusted, making these lasers “tunable” within the meaning of the present disclosure. The bank B can contain any number of tunable lasers, typically between 10 and 100. Of course, the invention is by no means limited to a bank of distributed feedback lasers, and applies to any tunable laser. A complementary example is a DBR laser (Distributed Bragg Reflector laser).

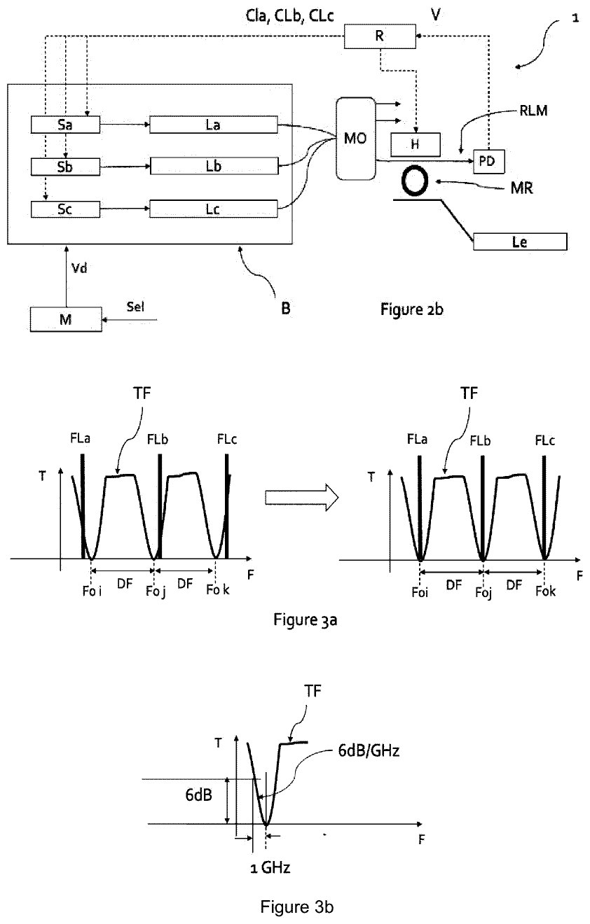

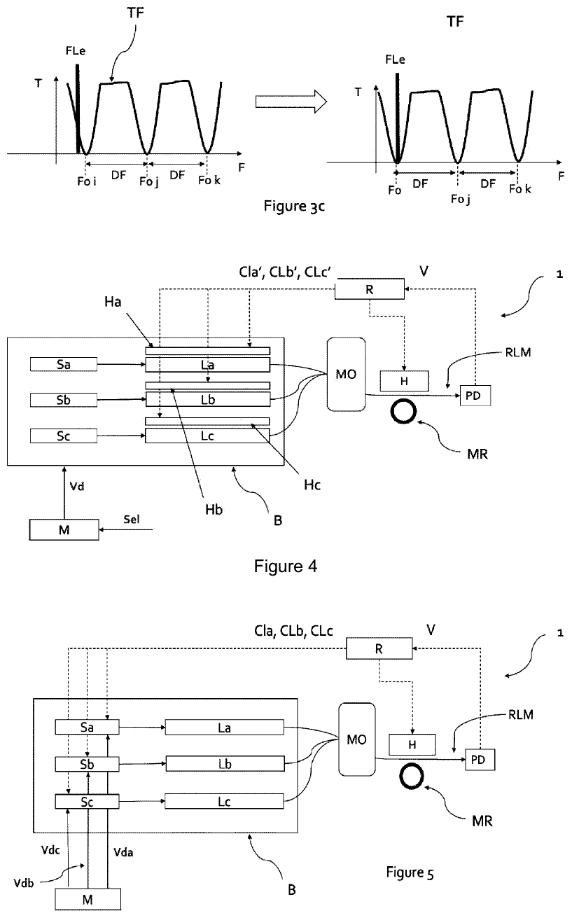

The lasers of the bank B are designed to emit light with stepped emission frequencies, typically within a 100 GHz spectral range for WDM applications, as previously described. However, as can be seen on the left-hand side of FIG. 3a (where the frequencies Fla, Flb, Flc and the filter transfer function FT are shown), the variability of the manufacturing method of the bank B means that the spectral interval separating the emission frequencies FLa, FLb, FLC of lasers of the bank B cannot be perfectly controlled. The spectral interval separating two successive lasers (ordered by emission frequency) is therefore variable, and this variation in the absence of any locking mechanism can be of the order of or greater than +/−20%. It will also be noted that the operating temperature of the bank B can affect laser emission frequencies and cause them to drift.

Returning to the disclosure in FIG. 2a, the tunable lasers La, Lb, Lc of the bank are coupled to an optical mixer MO via waveguides. This mixer MO produces at least one multispectral light emission RLM, a spectral line of which corresponds to an emission frequency of the light emission emitted by a tunable laser of the bank B. The mixer MO can provide a plurality of mutually identical multispectral light emissions.

The multispectral light emission RLM (or a plurality of such emissions) forms the so-called “useful” emission of the source 1, that is, the emission that can be exploited by other elements, optical modulators, optical switches, etc. when, for example, the source 1 forms a component of a communication system. At least part of the “useful” multispectral emission is sampled to align the emission frequencies of the tunable lasers of the bank B with a frequency comb having a specific spectral interval.

This sampled part of the multispectral light emission is guided via a waveguide to an optical filter MR with a transfer function TF defining a frequency comb template with the determined spectral interval DF, as shown in FIG. 3a. In other words, two successive resonant frequencies F0i, F0j, F0K of the filter MR are separated by a determined spectral interval DF. By way of example, the optical filter MR can be a resonator, such as a microring resonator or a Fabry Perrot resonator, which enables the spectral interval DF between two resonant frequencies F0i, F0j, F0K to be controlled precisely, for example to within 5%. Whatever its nature, the optical filter MR is positioned downstream of the bank B of tunable lasers, and more precisely downstream of the optical mixer MO, to receive the multispectral light emission RLM. In order to be able to discriminate, with sufficient sensitivity, a frequency deviation imparted by the modulation, the transfer function of the filter MR must be particularly narrow, preferentially with a slope greater than 6 dB/GHz, when deviating by one gigahertz or more from one of its resonant frequencies. Such a feature is shown in FIG. 3b.

The optical filter MR can comprise a device for adjusting the plurality of its resonant frequencies F0i, F0j, F0K. Thus, when the filter MR is implemented by a ring resonator, this device can be a heater H for frequency shifting the natural frequency comb, as will be explained in detail in a later section of the present disclosure.

The source 1 shown in FIG. 2a also comprises a photodetector PD arranged downstream of the optical filter MR to establish a signal V representative of the multispectral light emission MLR.

It also comprises a modulator M associated with the bank B of tunable lasers, the modulator M being controllable via a selection signal Sel. The function of the modulator M is to supply a signal Vd modulating the emission frequency of the light emission emitted by a tunable laser with a frequency modulation signal Fd. The modulation signal Vd, whose general form is of the type cos (2.Pi*Fd*t), has a relatively low modulation frequency Fd, of the order of a few kHz to a few MHz, typically of the order of 5 kHz, of some 10 KHz, or even 1 MHz or more. The amplitude of the modulation signal Vd is chosen so that the frequency deviation of the emission frequency of the light emission emitted by a tunable laser is of the order of 1 GHz or more. The selection signal Sel in this embodiment allows selection of the tunable laser of the bank B to which the modulation frequency Fd is to be applied.

In practice, this frequency modulation can be applied by modulating the current produced by the current source Sa, Sb, Sc associated with the selected tunable laser La, Lb, Lc with the modulation signal Vd. Other means of modulating the laser emission frequency can also be used. This may involve applying the modulation signal Vd to a heater associated with the laser, or to a free-carrier injection/depletion device in the laser. Generally speaking, then, the modulator M is electrically connected to the laser bank, so as to apply the modulation signal to a means of adjusting the emission frequency with which the selected tunable laser is equipped.

Finally, the laser source 1 shown in FIG. 2a comprises a locking device R for a tunable laser of the laser bank B. This locking device R is connected to the laser bank B via commands CLa, CLb, CLc respectively connected to the current sources Sa, Sb, Sc. It is also connected to the photodetector PD to receive the signal V established by this element and to the filter MR adjustment device H to control it. The locking device R is configured to control the modulator M and to select, by means of the selection signal Sel, the tunable laser to which the modulation signal Vd is applied. The locking device R is also configured, during a locking phase, to implement a control loop for tuning the selected tunable laser emission frequency Fla, Flb, Flc to a filter resonant frequency F0i, F0j, F0k. This control loop implements the principles described in relation to FIGS. 1a to 1c. In particular, it can perform a Fourier transform (or any other transform in the frequency domain) of the signal V produced by the photodetector PD and determine the proportion of power present in the modulation frequency Fd and in its harmonics, particularly in the second harmonic. It can also determine the phase of these signals. On this basis, the locking device R can generate the command associated with the selected tunable laser, enabling its emission frequency to be adjusted to lock onto a resonant frequency of the filter MR.

In the embodiment shown in FIG. 2a, the current sources Sa, Sb, Sc are adjustable, and a laser's emission frequency is adjusted by feedback control of its average supply current provided by the associated adjustable current source. As already stated, this average current, that is, the DC part of the laser supply current, affects the emission frequency of this laser.

The laser source 1 of the embodiment shown in FIG. 2a is operated, during a locking phase, by successively selecting a tunable laser to be locked from among the tunable lasers of the bank B. Thus, the locking device R may comprise a state machine emitting a selection signal Sel circularly selecting one of the tunable lasers of the bank B, for example during successive locking periods whose duration may typically be between a few microseconds and a few milliseconds. During each locking period, the locking device R implements the processing required to lock the emission frequency of the selected tunable laser to the natural frequency F0 closest to the optical filter MR. At the end of a complete cycle, each tunable laser is locked onto a specific frequency of the optical filter. In this locked state of the bank B, shown on the right-hand side of FIG. 3a, the multispectral light emission RLM conforms to the spectral template imposed by the optical filter MR: it exhibits a plurality of spectral lines FLa, FLb, FLc separated from one another by a spectral interval DF determined by the optical filter. Since the spectral interval DF between two adjacent natural frequencies F0 of the filter is controlled, typically to within 5% or better, this property can be imparted to the emission frequencies of the tunable lasers of the bank B.

By repeating the control cycles one after the other, in time-division multiplexing, it is possible to maintain the locked state of the bank of tunable lasers on the filter over time, and to compensate for any drifts, particularly those linked to variations in laser temperature.

Optionally, the locking device R can implement another control loop to calibrate the resonant frequency comb of the optical filter MR and to align it with absolute target resonant frequencies. To this end, and as shown in FIG. 2b, a light emission from an etalon laser Le is supplied to a complementary port of the filter MR. This etalon laser has a modulated emission frequency, just like the other tunable lasers La, Lb, Lc of the bank B. However, the tunable etalon laser Le is not connected to the locking device R, and its naturally stable emission frequency is not adjusted by this device.

The locking device R can extract, from the Fourier transform of the signal V produced by the photodetector PD, the frequency components corresponding to the modulation frequency of the tunable etalon laser and the locking device R can control the heater H, or any other device for adjusting the plurality of resonant frequencies F0i, F0j, F0k of the filter, in order to frequency shift this natural frequency comb and realign it with the target frequency supplied by the etalon laser. This operation is shown in FIG. 3c. This calibration control loop of the filter MR and the locking control loop of the tunable lasers are not necessarily distinct from one another, and according to one possible approach, the locking device R implements a single control loop or processing aimed at simultaneously optimizing the laser source 1 and the filter MR in order to produce a multispectral light emission RLM having a plurality of determined spectral lines, that is, each line of which is precisely positioned in the frequency domain.

It should be noted that the calibration of the resonant frequency comb of the optical filter MR described above is perfectly optional, and that the main purpose of the invention is to control the spectral interval present between the spectral lines of the multispectral emission produced by the laser source 1. In particular, it is perfectly acceptable for the absolute values of the emission frequencies of each tunable laser in the source to drift, particularly under the effect of the source's operating temperature, as long as the spectral intervals present between two adjacent spectral lines in the multispectral emission remain controlled.

FIG. 4 shows another example of the laser source 1. In this embodiment, each tunable laser La, Lb, Lc of the bank B is fitted with a heater Ha, Hb, Hc. As is well known, the heater associated with a laser enables fine control of the laser emission frequency by varying its temperature. In the configuration of the laser source 1 in this embodiment, the commands CLa′, CLb′, CLc′ generated by the locking device R are respectively connected to the heaters Ha, Hb, Hc in order to control them. In this embodiment, therefore, the emission frequency of the tunable lasers of the bank B is adjusted via the heaters Ha, Hb, Hc, by controlling the temperature of the selected tunable laser, and not by controlling its average supply current, as was the case in the first embodiment. All the other elements of the laser source 1 of the second embodiment are identical to those of the first embodiment and, for the sake of brevity, they will not be described again. It is of course possible to combine these two methods, and to adjust the emission frequency of the tunable lasers of the bank B by controlling both the average supply current of the current source associated with a selected tunable laser and, simultaneously, by controlling the temperature of this laser using an associated heater.

In another variant of the embodiments of the laser source 1 shown in FIGS. 2a and 4, each laser La, Lb, Lc of the bank B this time comprises a carrier injection/depletion device, e.g. A waveguide arranged beneath the laser La, Lb, Lc. In the same way, laser emission frequency can be finely controlled by varying the concentration of free carriers in the device beneath the laser. In the configuration of the laser source 1 in this embodiment, the commands CLa′, CLb′, CLc′ generated by the locking device R are respectively connected to the carrier injection/depletion devices.

As already stated, each tunable laser of the laser bank B can be provided with a plurality of means for adjusting its emission frequency. In this case, it is not necessary to use the same means to modulate the emission frequency of this laser and to adjust it to a resonant frequency of the filter MR. A first means can thus be used to modulate this emission frequency (e.g. by applying the modulation signal Vd to the supply current source of the selected laser and thus modulating this supply current) and a second means, different from the first, can be used to adjust the emission frequency of this laser to a resonant frequency of the filter (e.g. by controlling the temperature produced by a heater associated with the laser).

In the embodiment of FIG. 5, in frequency-division multiplexing mode, the modulator M generates a plurality of modulation signals Vda, Vdb, Vdc, each modulation signal being associated with a tunable laser La, Lb, Lc from the bank B. Each modulation signal has a modulation frequency Fda, Fdb, Fdc that is distinct from the frequencies of the other modulation signals. During a locking phase, these signals are applied simultaneously, and advantageously permanently, to the lasers with which they are respectively associated, in this case to the current sources of these lasers. The modulator M thus modulates the emission frequencies of the tunable lasers via a modulation frequency specific to each tunable laser. For example, the modulation frequencies can be in the range 1 kHz to 30 KHz. In the case of this embodiment, it is therefore not necessary for the modulator M to be controllable via a selection signal. The remainder of the laser source 1 in this embodiment is identical to the first embodiment in FIG. 2a, and it will therefore not be described here for the sake of brevity. In particular, as in the first embodiment, an emission supplied by an etalon laser can be injected into a complementary port of the filter MR, and a heater H associated with this filter MR can be used to precisely position each line of the multispectral light emission RLM in the frequency domain.

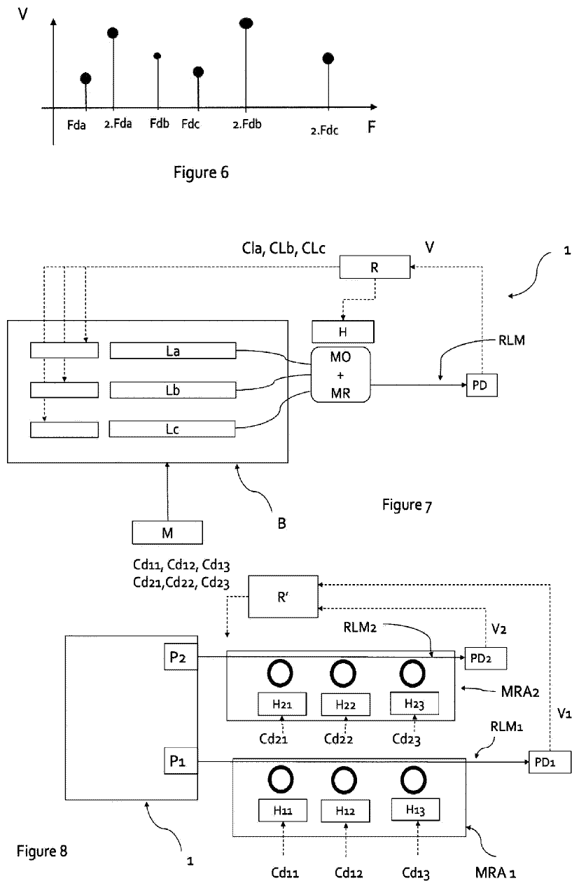

The processing implemented by the locking device R is naturally adapted to this design, but is based on the same principles described in FIGS. 1a to 1c. In particular, frequency-domain analysis of the signal V supplied by the photodetector reveals, as can be seen in FIG. 6, each of the modulation frequencies and their harmonics. Since these modulation frequencies are known, the locking device can be configured to identify them and implement processing to adjust the emission frequency of the associated tunable laser.

In the depiction of FIG. 5, the control signals CLa, CLb, CLc generated by the locking device R are respectively connected to the current sources Sa, Sb, Sc of the tunable laser bank. However, as in the embodiment shown in FIG. 4, it is also possible in the embodiment shown in FIG. 5 to control the emission frequency of the tunable lasers using heaters respectively associated with these tunable lasers, or any other means of adjusting the emission frequency of these lasers.

FIG. 7 shows a variant that can be applied to both the above-mentioned embodiments. In this variant, a single optical element (designated MO+MR in the figure) implements the functions of the mixer MO and the filter MR. For example, it may be a multiplexer implemented by an arrayed waveguide grating or a ladder network. This element has a transfer function identical to the one shown in FIG. 3a.

Very advantageously, the locking device R of a laser source 1 according to the invention also exploits the adjustment device H of the plurality of resonant frequencies of the optical filter MR, MO+MR in order to lock the emission frequencies of the light emissions of the tunable lasers. This approach can be deployed for all the embodiments presented above, and does not require the use of an etalon laser. It aims to control the spectral intervals between two adjacent spectral lines of the multispectral emission, without imposing the exact position of these spectral lines in absolute terms. In this way, it is possible to “float” the spectral positioning of the multispectral emission, while controlling the spectral intervals between two adjacent spectral lines. This thus avoids overloading the means for adjusting the emission frequency of the tunable lasers, by trying to force these frequencies to an absolute frequency, which could lead to affecting and excessively varying the power emitted by the laser (when, for example, the adjustment means are constituted by the laser current sources) or which could lead to excessive energy consumption by the source (when, for example, the adjustment means are constituted by heaters). It should be noted that in some cases, adjusting the emission frequency of a laser, when seeking to impose an absolute emission frequency, can lead to seeking to cool this source, which is not always easily possible.

The locking device R is configured so as, during a control phase that may precede the locking phase, to activate the device for adjusting H the plurality of resonant frequencies of the optical filter MR, in order to position these resonant frequencies relative to the laser emission frequencies in a so-called “average” configuration, which tends to bring the two frequency combs closer together. This average configuration is, for example, the one that will allow the means for adjusting the emission frequency of the tunable lasers to be used less intensively to lock the system, during the locking phase.

Numerous optimization criteria can be deployed by the locking device R during the control phase to establish this average configuration. This may for example involve optimizing the sum of the respective differences between the emission frequencies of the tunable lasers and the resonant frequencies of the filter. This can be a quadratic sum, or optimizing the maximum of these deviations, in absolute or relative terms.

Like in the locking phase, the locking device R uses the signal V established by the photodetector to determine the powers present in the second harmonic and/or in the fundamental of the modulation signal as well as the phase information of the modulation signal. This data can be used, for example using the graph in FIG. 1e, to determine the difference between a laser's emission frequency and the corresponding resonant frequency of the filter.

The locking device R can operate in time or frequency multiplexing during this control phase.

By way of example, it may be advisable to position the resonant frequencies of the filters during this control phase so that these frequencies are respectively higher, by a small margin, than the emission frequencies of the tunable lasers. It is then possible, during the locking phase, to adjust these emission frequencies upwards using heaters operated just when needed.

Regardless of the optimization criterion selected, the control device R can be configured to control the optical filter MR adjustment device H during this control phase and, for example, to scan its operating range. During this excursion, by time or frequency multiplexing the measurements, the control device R detects the differences between the resonant frequencies of the filter MR and the emission frequencies of the tunable lasers of the bank. At the end of this excursion, the control device identifies the command of the optical filter MR adjustment device H that best meets the chosen optimization criterion, and applies this command to the adjustment device H to place the filter in the average configuration. However, the control phase can be carried out using approaches other than the systematic approach of exploring the operating range of the adjustment device H. For example, a continuous optimization method can be applied, for example based on the gradient of the optimization criterion, during which the command of the adjustment device H of the optical filter MR is varied stepwise in order to seek an optimum of the optimization criterion. In all cases, and whatever the approach adopted, the control phase implemented by the control device R leads to the generation and application of a command to the adjustment device H aimed at placing the optical filter MR in an average configuration.

The control phase can precede the locking phase. This locking phase can be repeated at selected times to take into account any variations in the system's operating point. It is also possible to conduct the locking and control phases concurrently, for example in a single control loop, particularly when the control phase uses a continuous optimization technique of the gradient type. The laser emission frequencies and, collectively, the filter resonant frequencies are then adjusted simultaneously, with the aim of matching these frequencies as closely as necessary.

Regardless of the chosen embodiment, a laser source 1 conforming to the invention can be implemented using silicon-based photonic technologies. According to these technologies, waveguides and other passive components are produced on a silicon substrate (and advantageously on a silicon-on-insulator substrate) and other elements (laser sources, photodetectors, optical mixers, heaters) can be formed, by deposition or transfer, on this substrate. In particular, the bank B of tunable lasers, the optical filter MR with its adjustment device, the photodetector and the waveguides connecting these elements can be formed on the same photonic chip, that is, on/in the same substrate.

This photonic chip can be combined with an electronic chip comprising some of the other electronic components of the laser source 1, such as the current sources and even the locking device. In some cases, a single chip may comprise the photonic and electronic elements of the source 1. The locking device, if not integrated in one of the chips, can be implemented by a computing device (a microcontroller, a DSP signal processing computer or an ASIC) arranged on a support and to which the chip(s) are electrically connected.

It will be noted that since the bank B of tunable lasers and the optical filter MR are integrated on the same chip, on/in the same substrate, they are subject to the same temperature changes. This operating temperature affects the emission frequency of the tunable lasers, as well as the resonant frequency of the filter MR, especially when it is formed by a ring resonator. Advantageously, these elements are configured so that the temperature drift of the emission/resonant frequencies is identical or at least very similar. Thus, temperature drift coefficient (in mm/° C.) of the tunable laser emission frequencies and the temperature drift coefficient of the resonant frequencies can be identical to within 10%.

It will be noted that a laser source 1 conforming to the invention is particularly interesting, as it is possible to tune the emission frequency of the tunable lasers of the bank B using a particularly simple circuit. This is particularly true of the photonic part of the source, augmented by a single photodetector PD and a single filter MR, such as a microring resonator. This limits the number of additional interconnection pads required on the photonic chip to enable the locking functionality of tunable lasers.

The modulated multispectral light emission, which forms the “useful” emission provided by the source, can also be used to calibrate and/or lock photonic components (switches, modulators, etc.) downstream of the laser source 1, when this source 1 is used in a more complex system. An example of the use of a laser source according to the invention is shown in FIG. 8. In this figure, a laser source 1 has at least one output port (two ports P1, P2 in FIG. 8), each producing a multispectral light emission RLM1, RLM2. This emission is thus spectrally composed of a plurality of lines separated by a specific spectral interval. At least one of these lines is frequency-modulated, as has been explained in detail in connection with the description of each of the embodiments of the source 1 (in time or frequency multiplexing). The light emission RLM1, RLM2 produced by a port P1, P2 of the source 1 propagates in a waveguide coupled to this port P1, P2.

The waveguide itself is coupled to a photonic component comprising a filter with a tunable resonant frequency, in this case two modulators MRA1, MRA2, each implementing a network of microresonators. As is well known in the field of telecommunications, this modulator MRA1, MRA2 enables each spectral line of the multispectral light emission to be conditioned (here by means of microresonators tuned to these respective lines) to transmit information signals S1, S2, S3 in frequency-division multiplexed fashion. To enable the system shown in FIG. 8 to operate correctly, it may be advantageous to precisely tune the resonant frequencies of the resonators making up the modulators MRA1, MRA2 to the emission frequencies of the tunable lasers of the source 1, that is, the spectral lines making up the multispectral light emission RLM1, RLM2.

To enable this adjustment, the resonators of the network MRA1, MRA2 are associated with heaters H11, H12, H13 to adjust their resonant frequency to the spectral lines with which they are associated, and thus to tune the optical component. A monitoring photodetector P1, P2 is also provided, coupled to the waveguide to establish an electrical signal representative of the multispectral emission.

A regulator R′ collects the signal V1, V2 provided by the monitoring photodetector P1, P2 and produces the control signals Cd11, Cd12, Cd13; Cd21, Cd22, Cd23 for controlling the heaters H11, H12, H13; H21n, H22, H23 of the modulators MRA1, MRA2, and thus for adjusting the resonant frequencies of the microresonators. The controller uses the same principles as those shown in FIGS. 1a to 1e and 3c to determine these control signals.

Naturally, the invention is not limited to the embodiments described, and it is possible to add alternative embodiments without departing from the scope of the invention as defined by the claims.

1. A laser source for emitting at least one multispectral light emission having a plurality of spectral lines separated by a determined spectral interval, the laser source comprising:
a bank of tunable lasers, a spectral line of the multispectral light emission corresponding to a frequency of the light emission emitted by a tunable laser of the bank;
means for adjusting the emission frequencies of the tunable lasers;
an optical filter having a plurality of resonant frequencies, two successive resonant frequencies being separated by the determined spectral interval, the optical filter being arranged optically downstream of the bank of tunable lasers, the optical filter being provided with a device for adjusting the plurality of resonant frequencies;
a photodetector arranged optically downstream of the optical filter to establish a signal representative of the multispectral light emission transmitted through the filter;
a modulator associated with means for adjusting the emission frequencies of the tunable lasers, the modulator being configured to generate a modulation signal and to modulate the emission frequency of the light emission emitted by at least one tunable laser of the bank; and
a locking device connected to the means for adjusting the emission frequency of the tunable lasers and connected to the device for adjusting the plurality of resonant frequencies, the locking device being configured to process the signal representative of the multispectral emission and to lock the emission frequencies of the tunable lasers to the resonant frequencies of the filter.

2. The laser source according to claim 1, comprising an optical mixer associated with the bank of tunable lasers to combine the light emissions emitted by the tunable lasers of the bank and to provide the multispectral light emission to the filter.

3. The laser source according to claim 1, wherein the optical filter is a microring resonator.

4. The laser source according to claim 1, wherein the device for adjusting the plurality of resonant frequencies is a heater.

5. The laser source according claim 1, wherein the means for adjusting the emission frequency of the tunable lasers are selected from the following list: a current source, a heater, a free carrier injection/depletion device.

6. The laser source according to claim 1, wherein the lasers of the bank of tunable lasers are distributed feedback lasers or distributed Bragg reflector lasers.

7. The laser source according to claim 1, wherein the locking device is configured to control the modulator and to select, by means of the selection signal, the tunable laser to which the modulation signal is applied.

8. The laser source according to claim 1, wherein the modulator generates a plurality of modulation signals distinct from one another, the modulation signals being applied to the tunable lasers.

9. The laser source according to claim 1, wherein the modulator is configured to produce a sinusoidal modulation signal having a modulation frequency.

10. The laser source according to claim 9, wherein the locking device is configured to establish a measurement representative of the power present in a second harmonic or in a principal component or a measurement representative of the phase of the principal component of the modulation frequency of the signal representative of the multispectral emission.

11. The laser source according to claim 1, wherein the bank of tunable lasers and the optical filter are integrated on/in the same substrate of a photonic chip.

12. The laser source according to the claim 11, wherein the temperature drift coefficient of tunable laser emission frequencies and the temperature drift coefficient of resonant frequencies are identical to within 10%.

13. A method of using a laser source according claim 1, the method being implemented by the locking device and comprising:
a control phase to activate the device for adjusting the plurality of resonant frequencies of the optical filter; and
a locking phase to lock the light emission frequency of the selected tunable laser to a resonant frequency of the filter.

14. The method according to claim 13, wherein the locking phase is operated after the control phase.
